(19) United States
(12) Patent Application Publication
(10) Pub. No.: US 2016/0204061 A1
(43) Pub. Date: Jul. 14, 2016

(54) CHIP PACKAGE AND FABRICATION METHOD THEREOF

(71) Applicant: XINTEC INC., Taoyuan City (TW)

(72) Inventors: Ho-Yin YIU, Hsinchu City (TW); Ying-Nan WEN, Hsinchu City (TW); Chien-Hung LIU, New Taipei City (TW); Shih-Yi LEE, Taoyuan City (TW)

(21) Appl. No.: 14/992,776

(22) Filed: Jan. 11, 2016

Related U.S. Application Data
(60) Provisional application No. 62/102,320, filed on Jan. 12, 2015.

(51) Int. Cl. H01L 23/522; H01L 21/304; H01L 21/268; H01L 21/76; H01L 21/78; H01L 21/683; H01L 21/768; H01L 23/528

(52) U.S. Cl. CPC H01L 23/5226; H01L 21/76879; H01L 21/304; H01L 23/5283; H01L 21/76; H01L 21/78; H01L 21/6835; H01L 21/268; H01L 21/76802; H01L 21/76832

(57) ABSTRACT

A chip package including a chip, a first though hole, a conductive structure, a first isolation layer, a second though hole and a first conductive layer. The first though hole is extended from a second surface to a first surface to expose a conductive pad, and the conductive structure is on the second surface and extended to the first though hole to contact the conductive pad. The conductive structure includes a second conductive layer and a laser stopper. The first isolation layer is on the second surface and covering the conductive structure, and the first isolation layer has a third surface opposite to the second surface. The second though hole is extended from the third surface to the second surface to expose the laser stopper, and the first conductive layer is on the third surface and extended to the second though hole to contact the laser stopper.

### RELATED APPLICATIONS

This application claims priority to U.S. provisional Application Ser. No. 62/102,320, filed Jan. 12, 2015, which is herein incorporated by reference.

### BACKGROUND

1. Field of Invention

The present invention relates to a chip package and fabrication method thereof.

2. Description of Related Art

The finger print sensor and the RF (radio frequency) sensor require the use of a flat sensing surface to detect a signal, and the detecting accuracy of these sensing devices is reduced if the sensing surface is not flat. For example, a finger is pressed against the sensing surface of the finger print sensor. If the sensing surface is not flat, it will be difficult to detect complete fingerprint.

In addition, a through silicon via (TSV) is formed in a wafer to expose a pad from the TSV in the fabrication of the above sensing devices. Then, a chemical vapor deposition (CVD) process is applied to form a isolation layer on the pad and on the sidewalls of the TSV. After that, a patterning process is applied to form an opening in the isolation layer to expose the pad. Generally, the patterning process includes exposing, developing and etching processes. In the subsequent process, a redistribution layer is formed on the isolation layer and electrically connected to the pad exposed by the opening of the isolation layer.

However, the CVD and patterning processes are required to spend a lot process time and machine costs.

### SUMMARY

The present disclosure provides a chip package including a chip, a first though hole, a conductive structure, a first isolation layer, a second though hole and a first conductive layer. The chip has a conductive pad, a first surface and a second surface opposite to the first surface, and the conductive pad is on the first surface. The first though hole is extended from the second surface to the first surface to expose the conductive pad, and the conductive structure is disposed on the second surface and extended to the first though hole to contact the conductive pad. The conductive structure includes a second conductive layer and a laser stopper. The first isolation layer is on the second surface and covering the conductive structure, and the first isolation layer has a third surface opposite to the second surface. The second though hole is extended from the third surface to the second surface to expose the laser stopper, and the first conductive layer is on the third surface and extended to the second though hole to contact the laser stopper.

In various embodiments of the present disclosure, the chip package further includes a passivation layer and an b external conductive connection. The passivation layer is at the third surface and on the first conductive layer, and the passivation layer has an opening exposing the first conductive layer. The external conductive connection is in the opening and in contact with the first conductive layer.

In various embodiments of the present disclosure, a hole diameter of the second through hole is less than a hole diameter of the first through hole.

In various embodiments of the present disclosure, the chip package further includes a second isolation layer on the second surface and extending into the first through hole to cover sidewalls of the first through hole, and the conductive structure is on the second isolation layer.

In various embodiments of the present disclosure, a sidewall and a bottom of the second though hole are rough surfaces.

In various embodiments of the present disclosure, the first through hole and the second through hole are not overlapped in a vertical direction of projection.

In various embodiments of the present disclosure, a portion of the conductive structure in the first through hole is the second conductive layer, and a portion of the conductive structure on the second surface is the laser stopper.

In various embodiments of the present disclosure, the laser stopper is a thick copper having a thickness above the second surface, and the thickness being between 5 and 20 micrometers.

In various embodiments of the present disclosure, the second conductive layer is on the second surface and extending into the first through hole, and the laser stopper is on the second conductive layer.

In various embodiments of the present disclosure, the laser stopper is a gold bump.

In various embodiments of the present disclosure, the first isolation layer includes epoxy.

The present disclosure provides a method of fabricating a chip package, and the method includes following steps. A wafer is provided with a support body temporary bonding to the wafer, and the wafer has a conductive pad, a first surface and a second surface opposite to the first surface, which the conductive pad is on the first surface, and the support body covers the first surface and the conductive pad. A first though hole is formed extending from the second surface to the first surface to expose the conductive pad, and a conductive structure is formed on the second surface and on the conductive pad exposed from the first though hole, which the conductive structure includes a second conductive layer and a laser stopper. A first isolation layer is formed on the second surface to cover the conductive structure, and the first isolation layer has a third surface opposite to the second surface. A laser is used to remove a portion of the first isolation layer to form a second though hole, and the laser is stopped at the laser stopper to expose the laser stopper. A first conductive layer is formed on the third surface and on the laser stopper exposed from the second though hole.

In various embodiments of the present disclosure, the method further includes following steps. A passivation layer is formed on the third surface of the first isolation layer and on the first conductive layer, and the passivation layer is patterned to form an opening exposing the first conductive layer.

In various embodiments of the present disclosure, the method further includes forming an external conductive connection in the opening, and the external conductive connection is in contact with the first conductive layer.

In various embodiments of the present disclosure, the method further includes following steps. The support body is removed, and the wafer, the first isolation layer and the passivation layer are diced along a scribe line to form the chip package.

In various embodiments of the present disclosure, the laser is aligned to a location not overlapped with the first through hole in a vertical direction of projection.

In various embodiments of the present disclosure, forming the conductive structure includes following steps. The second conductive layer is formed on the conductive pad exposed from the first though hole, and the laser stopper is formed on the second surface, which the second conductive layer and the laser stopper are formed in the same process step.

In various embodiments of the present disclosure, forming the conductive structure includes following steps. The second conductive layer is formed on the second surface and on the conductive pad exposed from the first though hole, and the laser stopper is formed on the second conductive layer, which the second conductive layer and the laser stopper are formed in different process steps.

In various embodiments of the present disclosure, the laser stopper is formed on the second conductive layer by a gold bump method.

In various embodiments of the present disclosure, the method further includes following steps. A second isolation layer is formed on the second surface and in the first through hole, and the second isolation layer is patterned to expose the conductive pad.

### BRIEF DESCRIPTION OF THE DRAWINGS

The invention can be more fully understood by reading the following detailed description of the embodiment, with reference made to the accompanying drawings as follows:

FIG. 1 illustrates a top view of a chip package according to various embodiments of the present disclosure;

FIG. 2 illustrates a cross-sectional view of the chip package in FIG. 1 along the line A-A;

FIG. 3 illustrates an enlarge view of a portion of the chip package in FIG. 2;

FIG. 4 illustrates a cross-sectional view of the chip package in FIG. 1 along the line A-A, according to various embodiments of the present disclosure;

FIG. 5 illustrates an enlarge view of a portion of the chip package 400 in FIG. 4;

FIG. 6 illustrates a flow chart of a method of fabricating the chip package, in accordance with various embodiments;

FIGS. 7A to 7H are cross-sectional views of the chip package in FIG. 2 at intermediate stages of fabrication, in accordance with various embodiments;

FIGS. 8A to 8H are cross-sectional views of the chip package in FIG. 4 at intermediate stages of fabrication, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

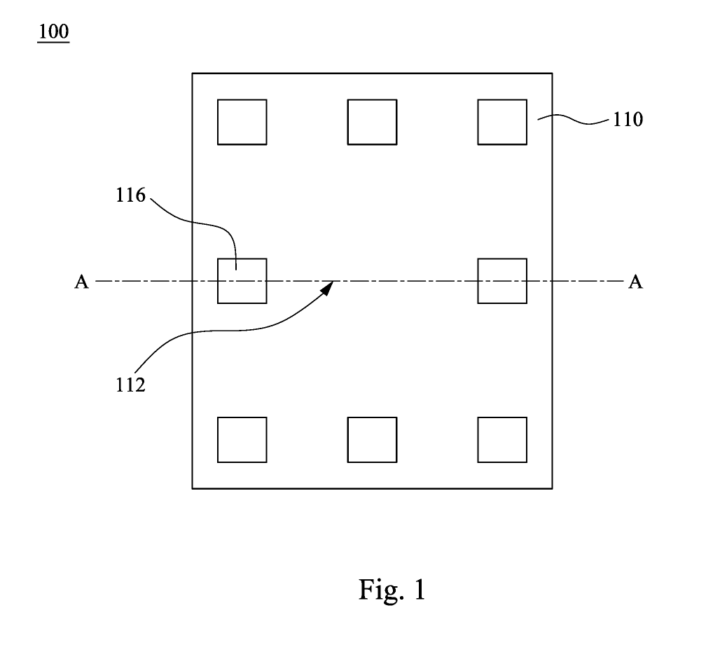

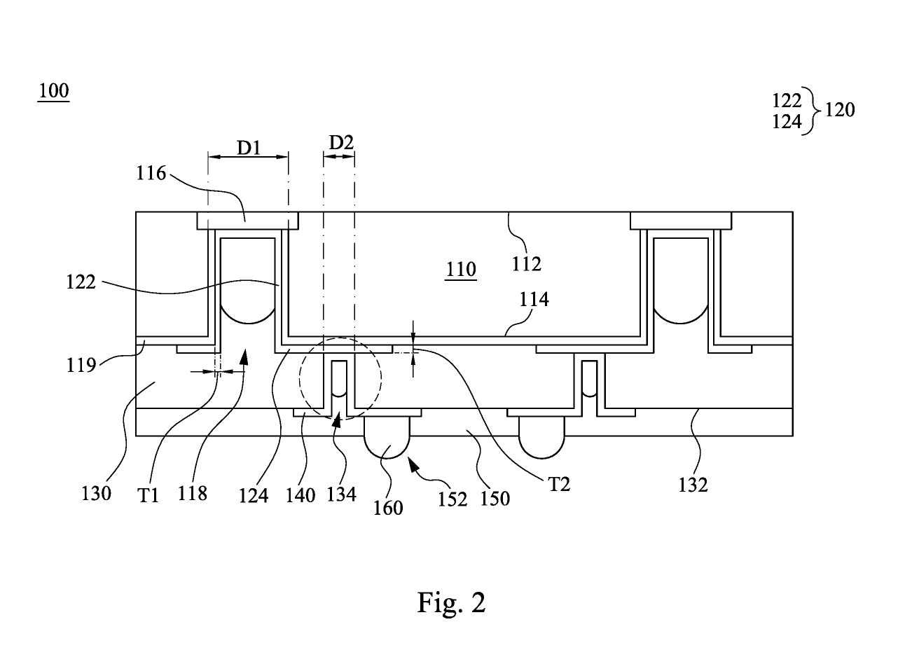

FIG. 1 illustrates a top view of a chip package according to various embodiments of the present disclosure, and FIG. 2 illustrates a cross-sectional view of the chip package in FIG. 1 along the line A-A. Refer to FIG. 1 and FIG. 2 at the same time. A chip package 100 includes a chip 110, a conductive structure 120, a first isolation layer 130, a first conductive layer 140, a passivation layer 150 and an external conductive connection 160. The chip 110 is a sensor chip having a first surface 112 and a second surface 114 opposite to the first surface 112, which the first surface 112 acts as a sensing surface, and a conductive pad 116 is on the first surface 112 of the chip 110. In some embodiments, the chip 110 is formed of silicon, germanium or group III-V compounds, but not limited thereto. In addition, the second surface 114 of the chip 110 has a first through hole 118 extending from the second surface 114 to the first surface 112 to expose the conductive pad 116.

The conductive structure 120 is on the second surface 114 and extended into the first through hole 118 to contact the conductive pad 116, and the conductive structure 120 is subdivided into a second conductive layer 122 and a laser stopper 124. Specifically, the conductive structure 120 has a portion in the first through hole 118, which is referred as the second conductive layer 122, and the second conductive layer 122 is in contact with the conductive pad 116 exposed from the first through hole 118. On the other hand, the conductive structure 120 has another portion on the second surface 114, which is referred as the laser stopper 124. The laser stopper 124 has the functionality of blocking a laser. In addition, a thickness T2 of the laser stopper 124 on the second surface 114 is greater than a thickness T1 of the second conductive layer 122 on sidewalls of the first through hole 118. The material of the conductive structure 120 is selected from a conductive material able to block the laser, such as copper, and the laser stopper 124 is a thick copper having a sufficient thickness to block the laser. In some embodiments, the thickness T2 of the laser stopper 124 on the second surface 114 is between 5 and 20 micrometers.

An angle between the sidewall of the first through hole 118 and the second surface 114 is 90 degrees illustrated in FIG. 2, but not limited thereto. The angle between the sidewall of the first through hole 118 and the second surface 114 may be greater than 90 degrees, equal to 90 degrees or less than 90 degrees, depending on process capability and design requirement of the chip.

In various embodiments, the chip package 100 further includes a second isolation layer 119 on the second surface 114 of the chip 110, a portion of the second isolation layer 119 being in the first through hole 118 to cover the sidewalls of the first through hole 118, and the conductive structure 120 is on the second isolation layer 119. In some embodiments, the second isolation layer 119 includes silicon oxide, silicon nitride, silicon oxynitride or other suitable insulating materials.

Continuing in FIG. 1 and FIG. 2, the first isolation layer 130 is on the second surface 114 to cover the conductive structure 120, which the first isolation layer 130 includes epoxy. It is worth noting that a portion of the first isolation layer 130 fills in, but not fully fill the first through hole 118, so a void is formed between the conductive pad 116 and the first isolation layer 130. It should be explained that the material of the first isolation layer 130, and the angle between the sidewall of the first through hole 118 and the second surface 114 are related to the formation of the void. Specifically, the first through hole 118 has a larger hole diameter D1 when the angle is greater than 90 degrees, and the first isolation layer 130 is easy to fully fill the first through hole 118. Therefore, a probability of forming the void is decreased, or the void is not even formed. Conversely, when the angle is less than or equal to 90 degrees, the first isolation layer 130 is not easy to fill in the first through hole 118, and the probability of forming the void is increased.

The first isolation layer 130 has a third surface 132 opposite to the second surface 114, and a second though hole 134 is extended from the third surface 132 to the second surface 114 to expose the laser stopper 124 of the conductive structure 120. The second though hole 134 is a laser through hole. Specifically, a laser is applied for penetrating the first isolation layer 130 to form the second through hole 134, and the laser stopper 124 of the conductive structure 120 on the second surface 114 acts as a terminal of the laser. Therefore, the laser stopper 124 prohibits the laser continually penetrating internal structures of the chip package 100. By applying the laser, a hole diameter D2 of the second through hole 134 is less than the hole diameter D1 of the first through hole 118, and it is benefit for miniaturization design. In addition, the first through hole 118 and the second through hole 134 are not overlapped in a vertical direction of projection.

Continuing in FIG. 1 and FIG. 2, the first conductive layer 140 is on the third surface 132 of the first isolation layer 130, and a portion of the first conductive layer 140 is in the second through hole 134 to contact the laser stopper 124, which is exposed from the second through hole 134. The passivation layer 150 is on the third surface 132 and on the first conductive layer 140, and the passivation layer 150 has an opening 152 exposing the first conductive layer 140. A portion of the passivation layer 150 fills in, but not fully fills the second through hole 134, so a void is formed between the first conductive layer 140 and the passivation layer 150. In addition, the external conductive connection 160 is in the opening 152 and in contact with the first conductive layer 140. The external conductive connection 160 is electrically connected to the conductive pad 116 by the first conductive layer 140, the laser stopper 124 and the second conductive layer 122.

In some embodiments, the external conductive connection 160 includes a solder ball, a bump or other well-known structures in the industry, and a shape of the external conductive connection 160 includes spherical, oval, square or rectangular, but not limited thereto. In various embodiments, the first conductive layer 140 includes conductive materials, such as copper.

In some embodiments, the chip package 100 is finger print sensor or a RF sensor, but not limited thereto.

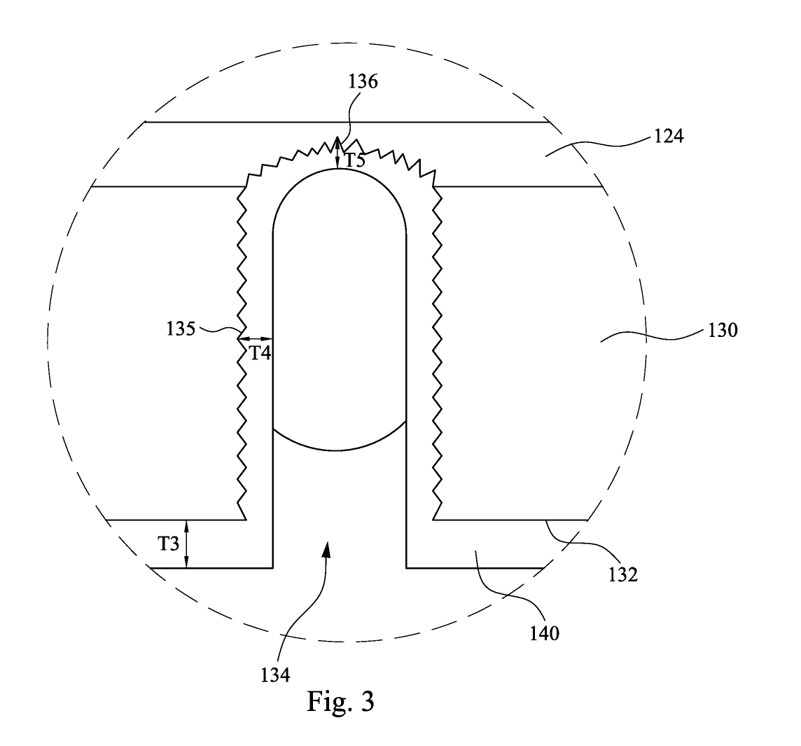

FIG. 3 illustrates an enlarge view of a portion of the chip package 100 in FIG. 2. As shown in FIG. 3, the laser is applied to form the second through hole 134, and the laser stopper 124 of the conductive structure 120 acts as the terminal of the laser. Even though a portion of the laser stopper 124 is removed by the laser, but the laser is not able to penetrate the laser stopper 124. In addition, sidewalls 135 and a bottom 136 of the second though hole 134 are rough surfaces since the second through hole 134 is formed by the laser, and the laser stopper 124 is exposed at the bottom 136 of the second through hole 134.

After forming the second through hole 134, the first conductive layer 140 is formed on the third surface 132 of the first isolation layer 130. The first conductive layer 140 is further extended to cover the sidewalls 135 and the bottom 136 of the second through hole 134, so as the first conductive layer 140 is electrically connected to the laser stopper 124. Since the first conductive layer 140 is formed by electroplating, a thickness T3 of the first conductive layer 140 on the third surface 132 of the first isolation layer 130 is greater than a thickness T4 of the first conductive layer 140 on the sidewalls 135 of the second through hole 134, and the thickness T4 of the first conductive layer 140 on the sidewalls 135 of the second through hole 134 is greater than a thickness T5 of the first conductive layer 140 on the bottom 136 of the second through hole 134.

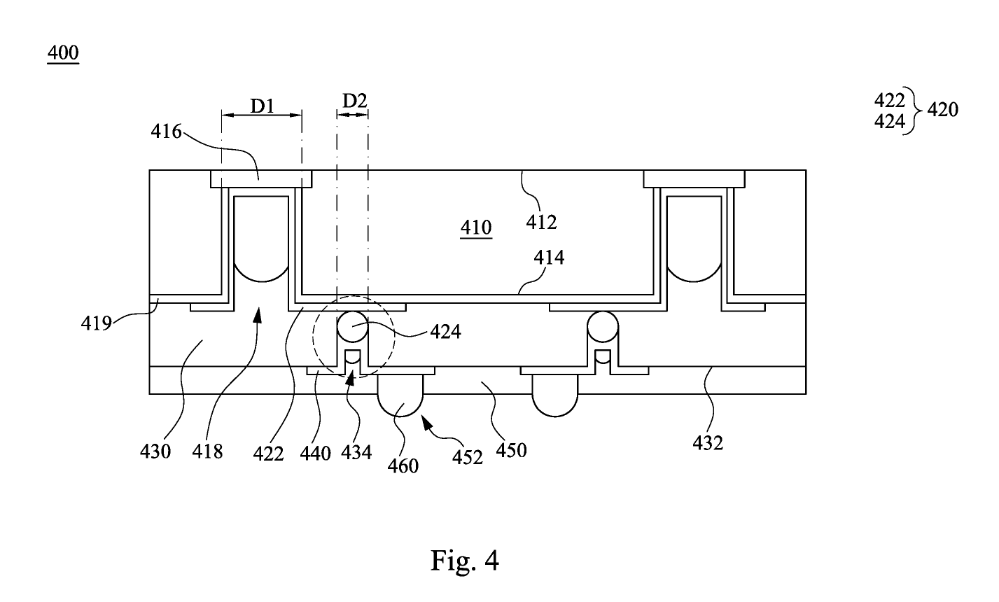

Referring now to FIG. 4. FIG. 4 illustrates a cross-sectional view of the chip package in FIG. 1 along the line A-A, according to various embodiments of the present disclosure. It should be noticed that the materials of the same elements are not described herein.

As shown in FIG. 4, a chip package 400 includes a chip 410, a conductive structure 420, a first isolation layer 430, a first conductive layer 440, a passivation layer 450 and an external conductive connection 460. The chip 410 is a sensor chip having a first surface 412 and a second surface 414 opposite to the first surface 412, which the first surface 412 acts as a sensing surface, and a conductive pad 416 is on the first surface 412 of the chip 410. The second surface 414 of the chip 410 has a first through hole 418 extending from the second surface 414 to the first surface 412 to expose the conductive pad 416. The conductive structure 420 is on the second surface 414, and the conductive structure 420 shown in FIG. 4 includes a second conductive layer 422 and a laser stopper 424. The second conductive layer 422 is on the second surface 414 and extended into the first through hole 418 to contact the conductive pad 416 exposed from the first through hole 418, and the laser stopper 424 is on and in contact with the second conductive layer 422.

An angle between the sidewall of the first through hole 418 and the second surface 414 is 90 degrees illustrated in FIG. 4, but not limited thereto. The angle between the sidewall of the first through hole 418 and the second surface 414 may be greater than 90 degrees, equal to 90 degrees or less than 90 degrees, depending on process capability and design requirement of the chip.

In various embodiments, the chip package 400 further includes a second isolation layer 419 on the second surface 414 of the chip 410, a portion of the second isolation layer 419 being in the first through hole 418 to cover the sidewalls of the first through hole 418, and the second conductive layer 422 is on the second isolation layer 419.

Continuing in FIG. 4, the first isolation layer 430 is on the second surface 414 to cover the conductive structure 420 (the second conductive layer 422 and the laser stopper 424). It is worth noting that a portion of the first isolation layer 430 fills in, but not fully fills the first through hole 418, so a void is formed between the conductive pad 416 and the first isolation layer 430. As aforementioned, the material of the first isolation layer 430, and the angle between the sidewall of the first through hole 418 and the second surface 414 are related to the formation of the void, so the first through hole 418 may be fully filled by the first isolation layer 430 without forming the void.

The first isolation layer 430 has a third surface 432 opposite to the second surface 414, and a second though hole 434 is extended from the third surface 432 to the second surface 414 to expose the laser stopper 424 of the conductive structure 420. The second though hole 434 is a laser through hole. Specifically, a laser is applied for penetrating the first isolation layer 430 to form the second through hole 434, and the laser stopper 424 of the conductive structure 420 prohibits the laser continually penetrating internal structures of the chip package 400. By applying the laser, a hole diameter D2 of the second through hole 434 is less than the hole diameter D1 of the first through hole 418, and it is benefit for miniaturization design. In addition, the first through hole 418 and the second through hole 434 are not overlapped in a vertical direction of projection.

The difference between the chip package 400 in FIG. 4 and the chip package 100 in FIG. 2 is that a material of the laser stopper 424 in the chip package 400 is selected from a conductive material able to block the laser, such as copper and gold. By applying the laser stopper 424, a material of the second conductive layer 422 could be selected from any suitable conductive materials, such as aluminum, copper or nickel. In some embodiments, the laser stopper 424 is a gold bump.

Continuing in FIG. 4, the first conductive layer 440 is on the third surface 432 of the first isolation layer 430, and a portion of the first conductive layer 440 is in the second through hole 434 to contact the laser stopper 424, which is exposed from the second through hole 434. The passivation layer 450 is on the third surface 432 and the on first conductive layer 440, and the passivation layer 450 has an opening 452 exposing the first conductive layer 440. A portion of the passivation layer 450 fills in, but not fully fills the second through hole 434, so a void is formed between the first conductive layer 440 and the passivation layer 450. In addition, the external conductive connection 460 is in the opening 452 and in contact with the first conductive layer 440. The external conductive connection 460 is electrically connected to the conductive pad 416 by the first conductive layer 440, the laser stopper 424 and the second conductive layer 422.

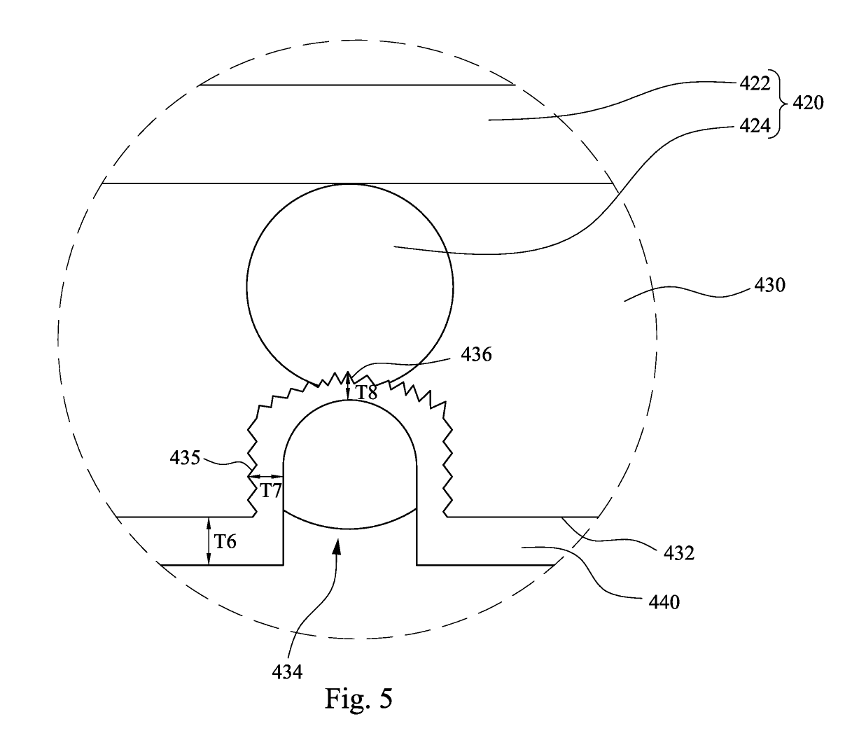

FIG. 5 illustrates an enlarge view of a portion of the chip package 400 in FIG. 4. As shown in FIG. 5, the laser is applied to the formation of the second through hole 134, and the laser stopper 424 of the conductive structure 420 acts as a terminal of the laser. A portion of the laser stopper 424 is removed by the laser, but the laser is not able to penetrate the laser stopper 424. In addition, sidewalls 435 and a bottom 436 of the second though hole 434 are rough surfaces since the second through hole 434 is formed by the laser, and the laser stopper 424 is exposed at the bottom 436 of the second through hole 434.

After forming the second through hole 434, the first conductive layer 440 is formed on the third surface 432 of the first isolation layer 430. The first conductive layer 440 is further extended to cover the sidewalls 435 and the bottom 436 of the second through hole 434, so that the first conductive layer 440 is electrically connected to the laser stopper 424. Since the first conductive layer 440 is formed by electroplating, a thickness T6 of the first conductive layer 440 on the third surface 432 of the first isolation layer 430 is greater than a thickness T7 of the first conductive layer 440 on the sidewalls 435 of the second through hole 434, and the thickness T7 of the first conductive layer 440 on the sidewalls 435 of the second through hole 434 is greater than a thickness T8 of the first conductive layer 440 on the bottom 436 of the second through hole 434.

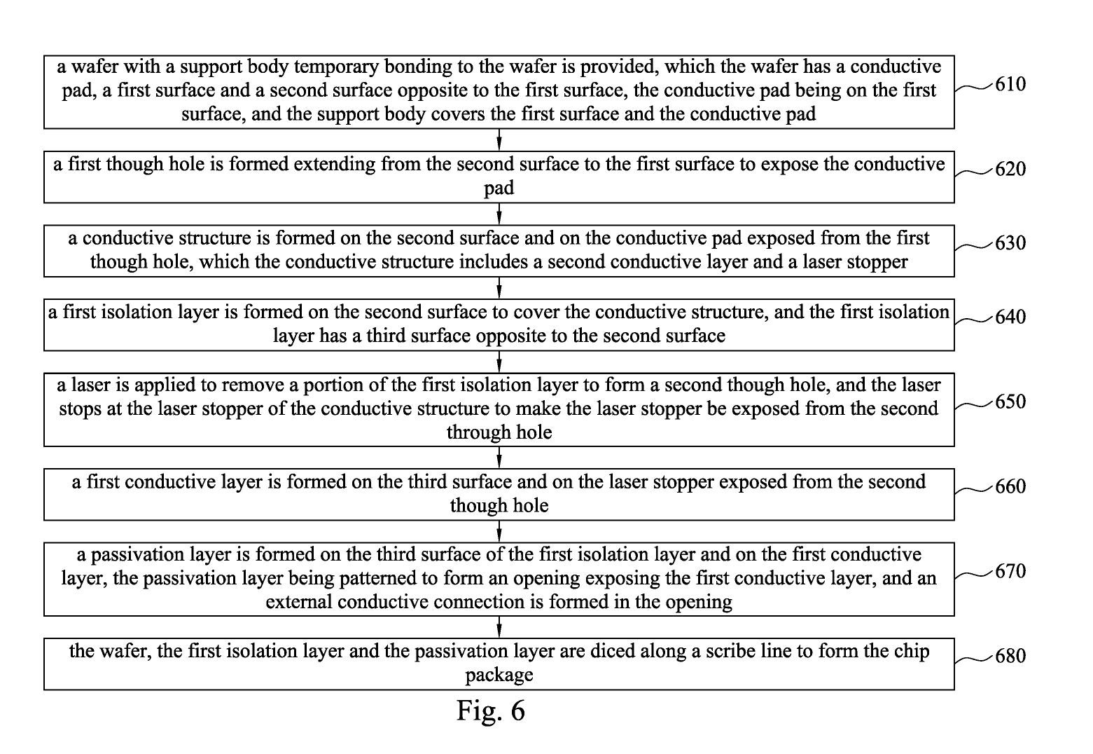

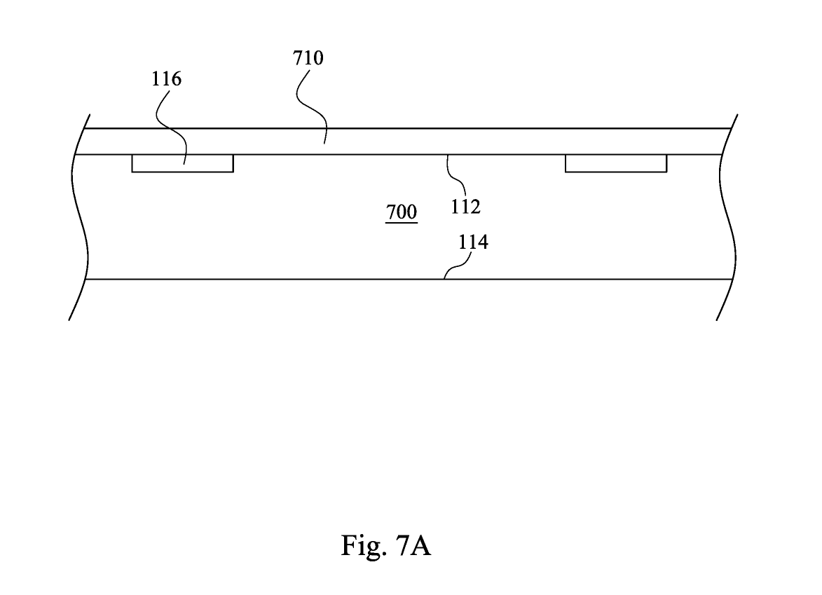

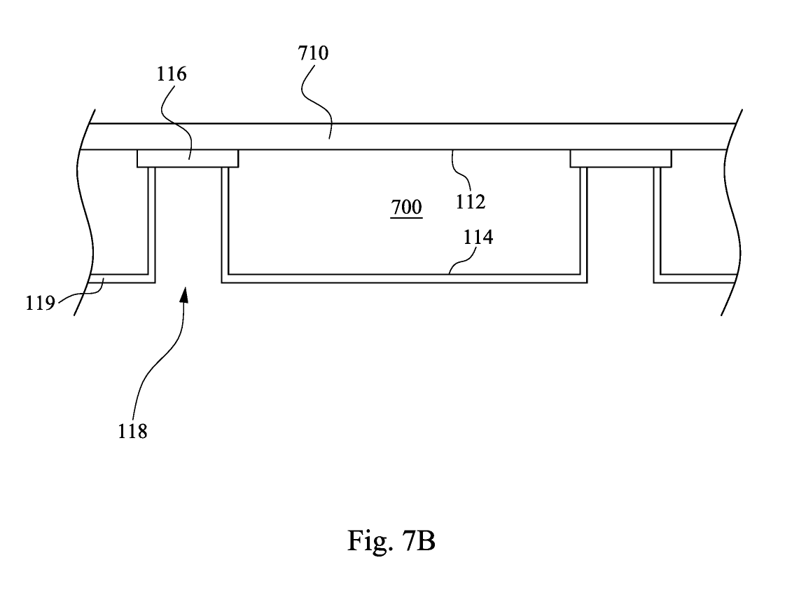

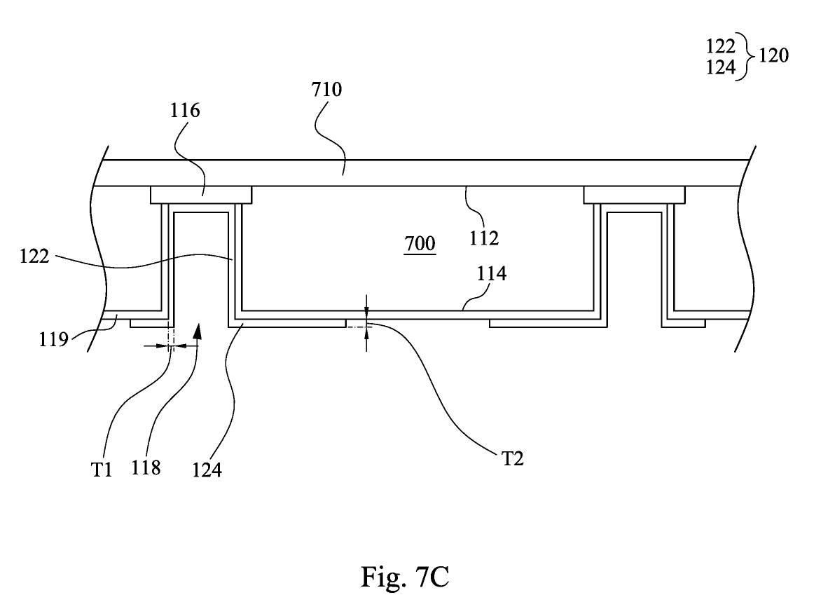

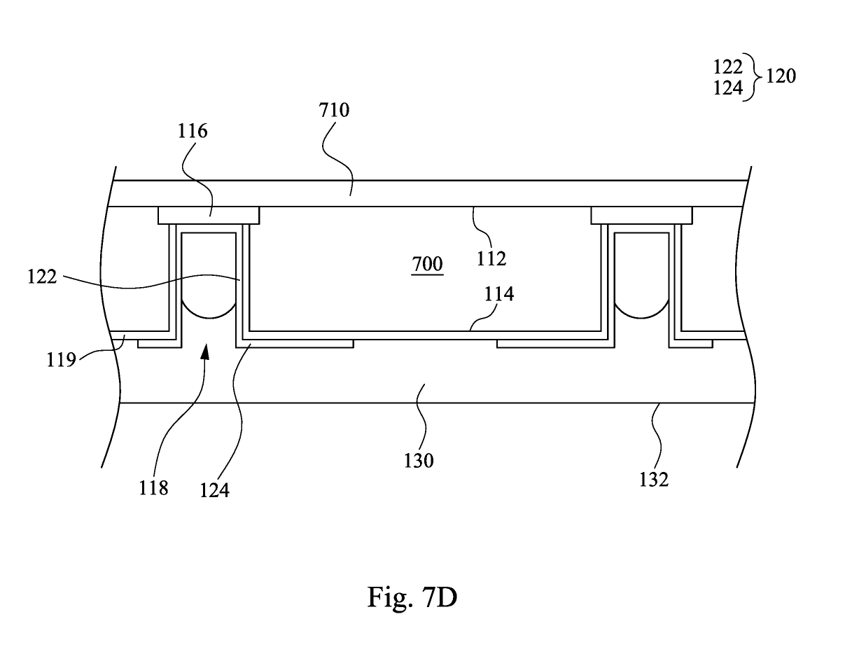

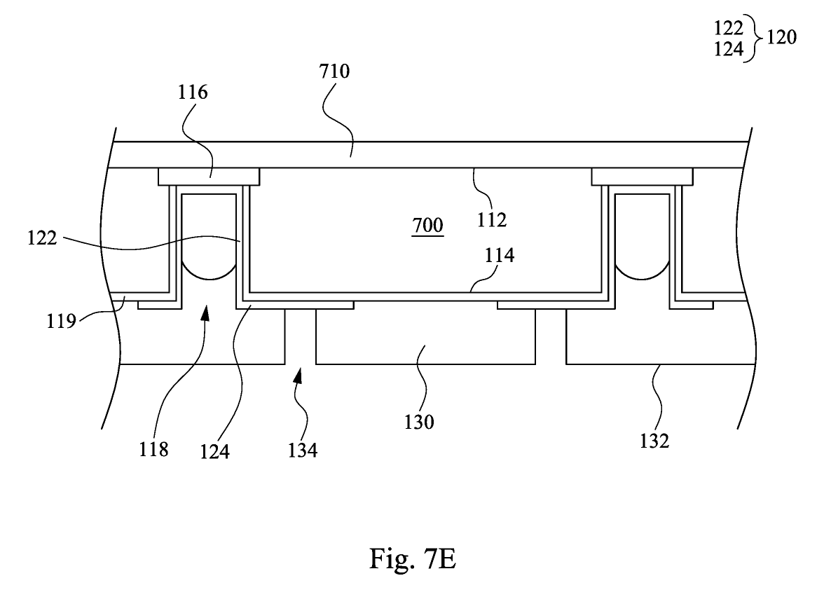

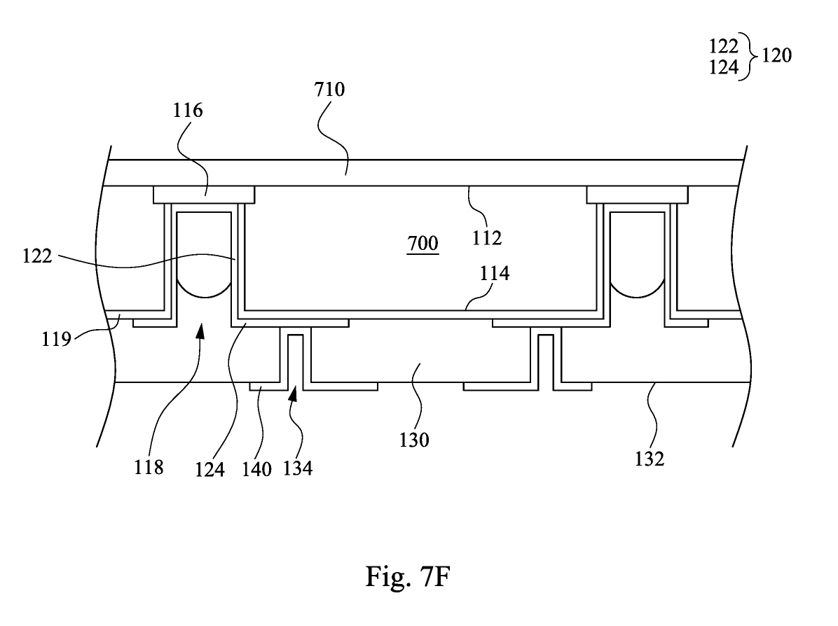

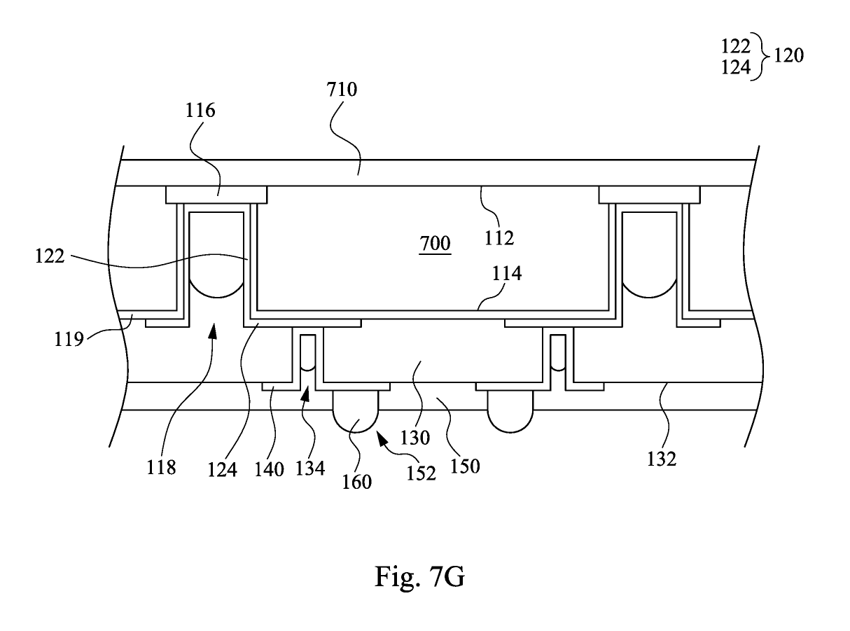

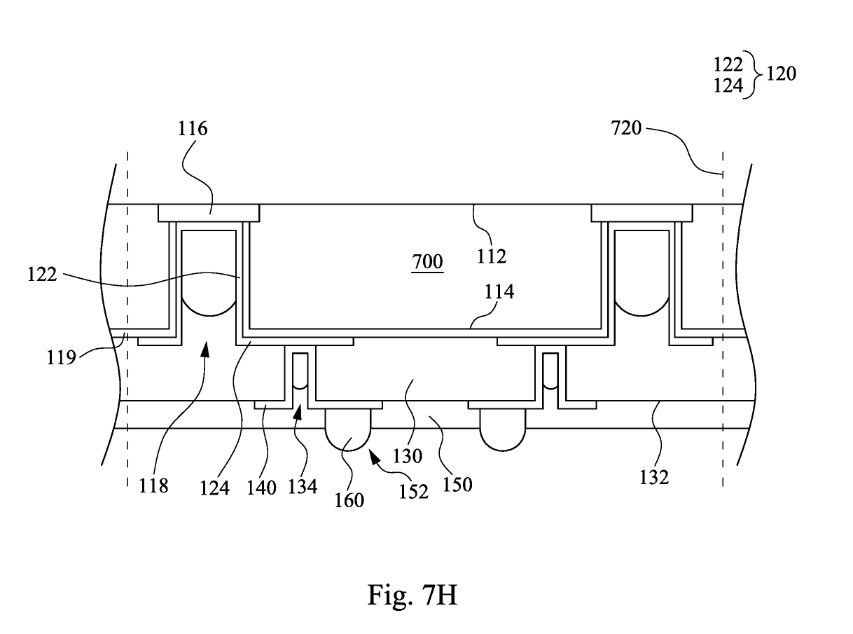

Referring to FIG. 6, FIG. 6 illustrates a flow chart of a method of fabricating the chip package, in accordance with various embodiments. Refer to FIGS. 7A to 7H at the same time to further understand the method of fabricating the chip package, which FIGS. 7A to 7H are cross-sectional views of the chip package in FIG. 2 at intermediate stages of fabrication, in accordance with various embodiments.

Refer to step 610 and FIG. 7A, a wafer 700 with a support body 710 temporary bonding to the wafer 700 is provided, which the wafer 700 has a conductive pad 116, a first surface 112 and a second surface 114 opposite to the first surface 112. The conductive pad 116 is on the first surface 112, and the support body 710 covers the first surface 112 and the conductive pad 116. The wafer 700 is a semiconductor substrate, which a plurality of chips shown in FIG. 2 are formed by dicing the wafer 700, and the support body 710 may provide support force in the subsequent process to prevent external force cracking the wafer 700. In some embodiments, the second surface 114 of the wafer 700 is further polished after bonding the wafer 700 and the support body 710, so as to reduce a thickness of the wafer 700.

Refer now to step 620 and FIG. 7B, a first though hole 118 is formed extending from the second surface 114 to the first surface 112 to expose the conductive pad 116. The first through hole 118 may be formed by, for example, photolithography etching, but not limited thereto. In some embodiments, after forming the first through hole 118, a second isolation layer 119 is further formed on the second surface 114 and in the first through hole 118. Then, a portion of the second isolation layer 119 is photolithography etched to expose the conductive pad 116 from the first through hole 118. In some embodiments, an angle between the sidewall of the first through hole 118 and the second surface 114 may be greater than 90 degrees, equal to 90 degrees or less than 90 degrees.

Continuing in step 630 and FIG. 7C, a conductive structure 120 is formed on the second surface 114 and on the conductive pad 116 exposed from the first though hole 118, which the conductive structure 120 includes a second conductive layer 122 and a laser stopper 124. It has to be explained that the second conductive layer 122 and the laser stopper 124 are formed in the same process step. In this step, a conductive material is deposited on the conductive pad 116 exposed from the first through hole 118 to form the second conductive layer 122, and the conductive material is simultaneously deposited on the second surface 114 to form the laser stopper 124, and therefore accomplish the fabrication of the conductive structure 120. In some embodiments, the conductive material may be deposited using sputtering, evaporating, electroplating or electroless plating. In this embodiment, the second conductive layer 122 and the laser stopper 124 of the conductive structure 120 are formed of copper, which the laser stopper 124 is a thick copper having a thickness T2 above the second surface 114, and the thickness T2 is between 5 and 20 micrometers. In some embodiments, the second isolation layer 119 is formed first, and the conductive material is deposited on the second isolation layer 119 to form the conductive structure 120.

Continuing in step 640 and FIG. 7D, a first isolation layer 130 is formed on the second surface 114 to cover the conductive structure 120. That is, the first isolation layer 130 covers the second conductive layer 122 and the laser stopper 124, and the first isolation layer 130 has a third surface 132 opposite to the second surface 114. In this step, an epoxy is printed or coated on the second surface 114 of the wafer 700, so as to form the first isolation layer 130 covering the conductive structure 120. In addition, a portion of the first isolation layer 130 fills in, but not fully fills the first through hole 118. In some embodiments, the third surface 132 of the first isolation layer 130 is further coated, imprinted, molded or polished to reduce a thickness of the first isolation layer 130.

Continuing in step 650 and FIG. 7E, a laser is applied to remove a portion of the first isolation layer 130 to form a second though hole 134, and the laser stops at the laser stopper 124 of the conductive structure 120 to make the laser stopper 124 be exposed from the second through hole 134. In this step, the laser is aligned to the laser stopper 124 on the second surface 114. Since the laser is not able to penetrate the laser stopper 124, which acts as a terminal of the laser and being exposed from the second through hole 134. In some embodiments, the laser is aligned to a location not overlapped with the first through hole 118 in a vertical direction of projection.

Continuing in step 660 and FIG. 7F, a first conductive layer 140 is formed on the third surface 132 and on the laser stopper 124 exposed from the second though hole 134. After forming the second through hole 134 in the first isolation layer 130, a conductive material is deposited on the third surface 132 of the first isolation layer 130, sidewalls of the second through hole 134 and the laser stopper 124 exposed from the second through hole 134, so as to form the first conductive layer 140, which the conductive material is deposited by using electroless plating in combination with electroplating. In some embodiments, the first conductive layer 140 is formed of copper.

Continuing in step 670 and FIG. 7G, a passivation layer 150 is formed on the third surface 132 of the first isolation layer 130 and on the first conductive layer 140, and the passivation layer 150 is patterned to form an opening 152 exposing the first conductive layer 140. Then, an external conductive connection 160 is formed in the opening 152. Insulating material is brush-coated on the third surface 132 of the first isolation layer 130 and on the first conductive layer 140, so as to form the passivation layer 150, and the insulating material includes epoxy. In addition, a portion of the passivation layer 150 fills in, but not fully fills the second through hole 134. After that, the passivation layer 150 is patterned to form the opening 152, and a portion of the first conductive layer 140 is exposed from the opening 152 of the passivation layer 150. Then, the external conductive connection 160 is formed in the opening 152. The external conductive connection 160 is electrically connected to the conductive pad 116 by the first conductive layer 140, the laser stopper 124 and the second conductive layer 122.

In some embodiments, the support body 710 on the first surface 112 of the wafer 700 is removed after forming the passivation layer 150. In some embodiments, the support body 710 on the first surface 112 of the wafer 700 is removed after forming the external conductive connection 160.

Continuing in step 680 and FIG. 7H, the wafer 700, the first isolation layer 130 and the passivation layer 150 are diced along a scribe line 720 to form the chip package 100. The wafer 700 is diced alone the scribe line 720 to separate the chips on the wafer, so as to form the chip package 100 shown in FIG. 2.

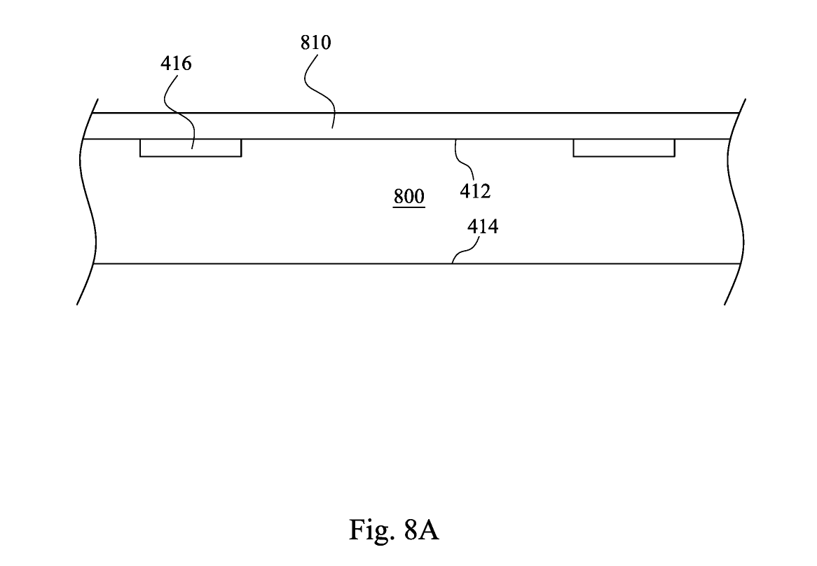

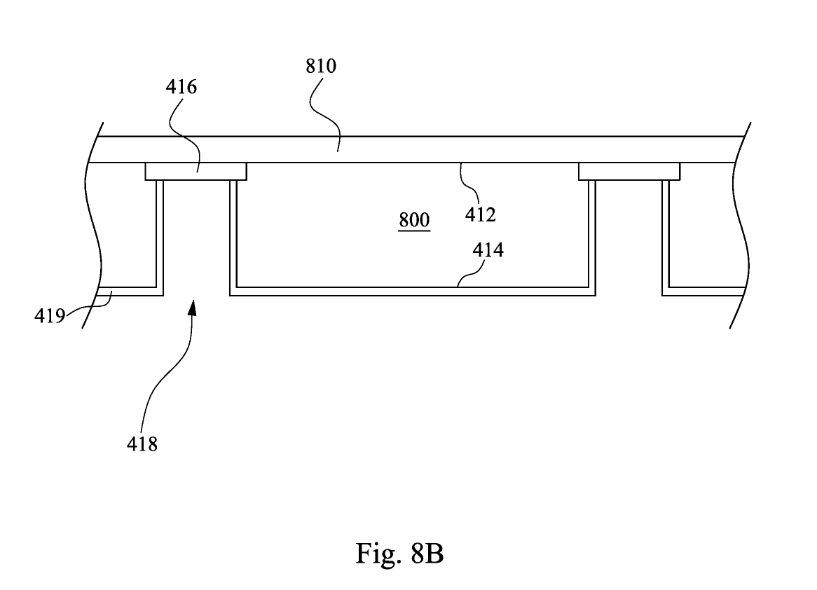

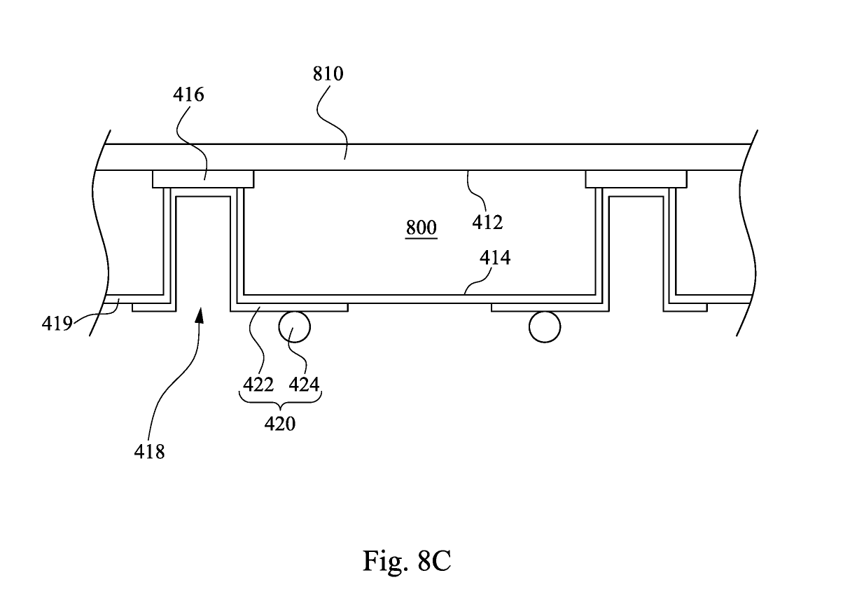

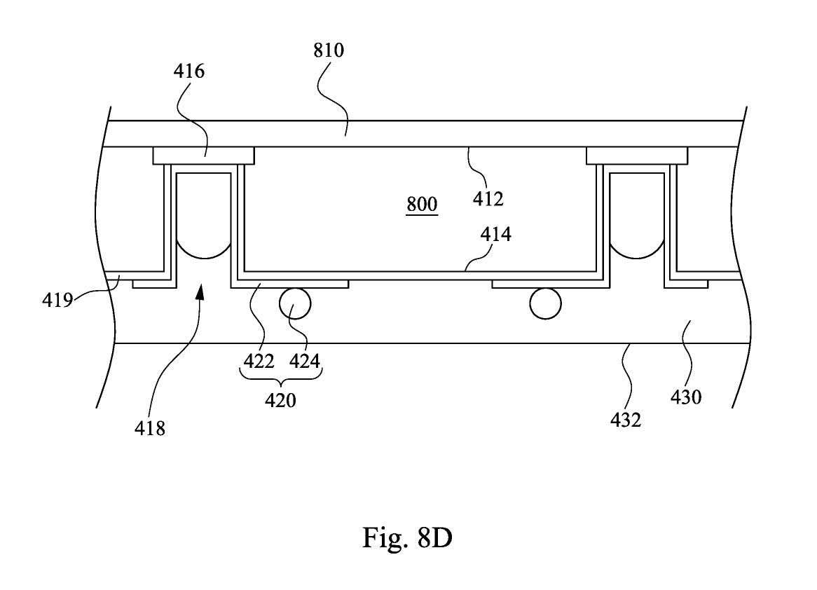

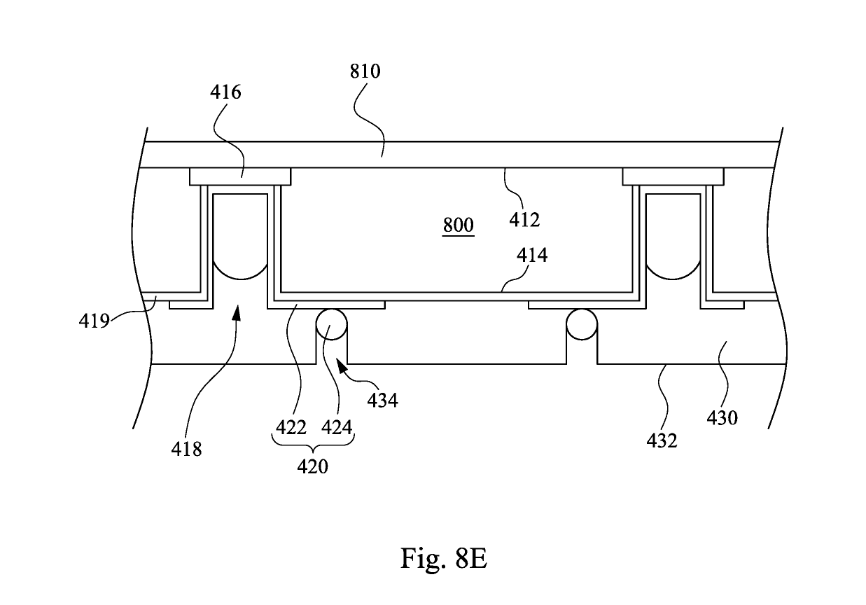

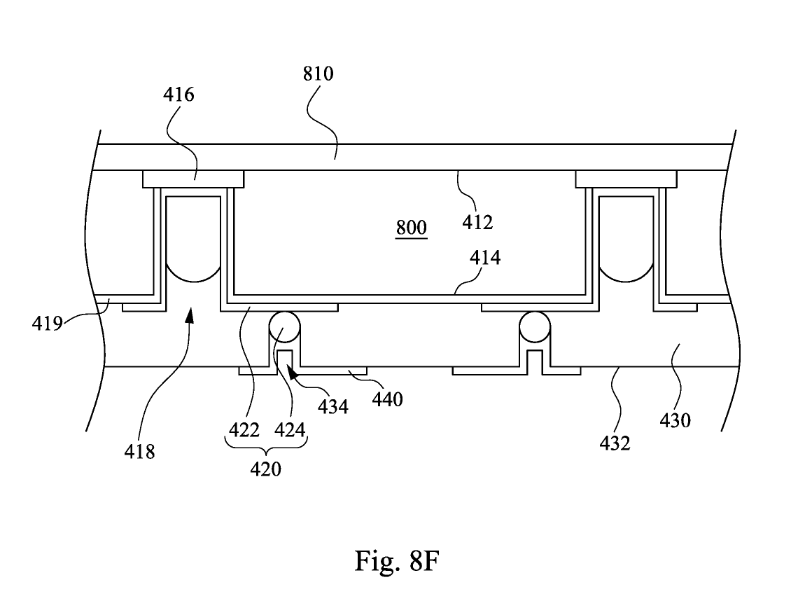

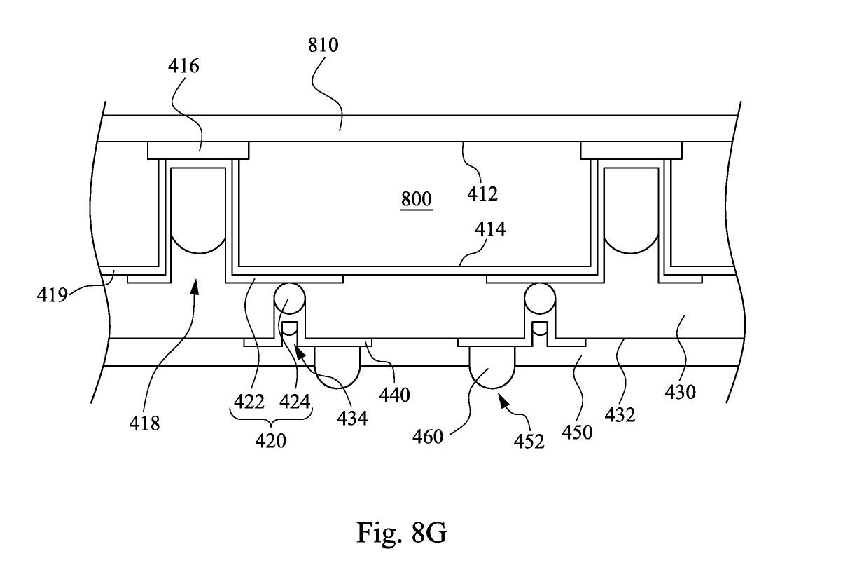

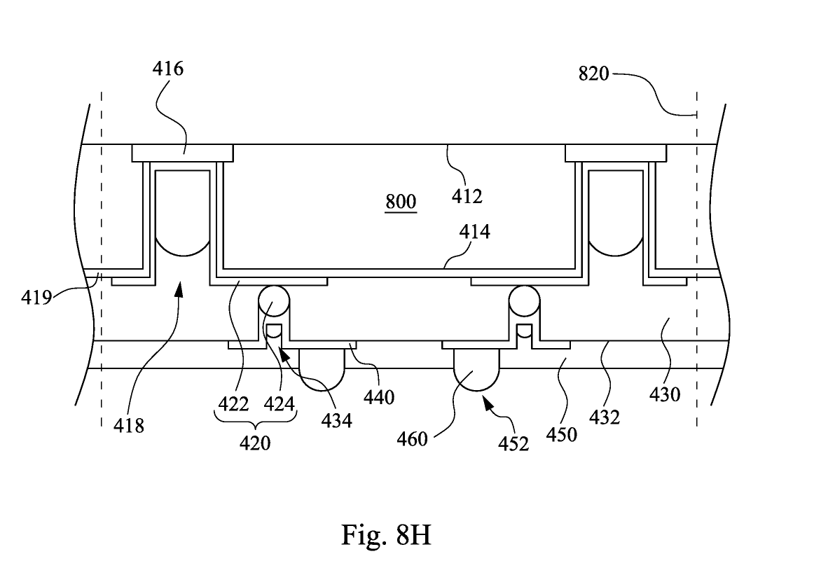

Refer to FIGS. 8A to 8H to further understand a method of fabricating the chip package in accordance with various embodiments of the present disclosure. FIGS. 8A to 8H are cross-sectional views of the chip package in FIG. 4 at intermediate stages of fabrication, in accordance with various embodiments.

In FIG. 8A, a wafer 800 with a support body 810 temporary bonding to the wafer 800 is provided, which the wafer 800 has a conductive pad 416, a first surface 412 and a second surface 414 opposite to the first surface 412. The conductive pad 416 is on the first surface 412, and the support body 810 covers the first surface 412 and the conductive pad 416. The wafer 800 is a semiconductor substrate, which a plurality of chips 410 shown in FIG. 4 are formed by dicing the wafer 800, and the support body 810 provides support force in the subsequent process to prevent from the wafer 800 being cracked by the external force.

In FIG. 8B, a first though hole 418 is formed extending from the second surface 414 to the first surface 412 to expose the conductive pad 416. The first through hole 418 may be formed by, for example, photolithography etching, but not limited thereto. In some embodiments, after forming the first through hole 418, a second isolation layer 419 is further formed on the second surface 414 and in the first through hole 418. Then, a portion of the second isolation layer 419 is photolithography etched to expose the conductive pad 416 from the first through hole 418. In some embodiments, an angle between the sidewall of the first through hole 418 and the second surface 414 may be greater than 90 degrees, equal to 90 degrees or less than 90 degrees.

Continuing in FIG. 8C, a conductive structure 420 is formed on the second surface 414 and on the conductive pad 416 exposed from the first though hole 418, which the conductive structure 420 includes a second conductive layer 422 and a laser stopper 424. The difference between FIG. 7C and FIG. 8C is that the second conductive layer 422 and the laser stopper 424 are formed in different process steps. First, sputtering, evaporating, electroplating or electroless plating techniques may be applied to deposit a conductive material on the second surface 414 and on the conductive pad 416 exposed from the first through hole 418, so as to form the second conductive layer 422. Then, the laser stopper 424 is further formed on the second conductive layer 422. In some embodiments, the laser stopper 424 is a gold bump, which is formed on the second conductive layer 422 by a gold bump method. The “gold bump method” means that a gold line having the gold bump is wired on the second conductive layer 422, and the gold line is cut to remain the gold bump on the second conductive layer 422. In some embodiments, the second conductive layer 422 includes copper, nickel, aluminum, or other suitable conductive material.

Continuing in FIG. 8D, a first isolation layer 430 is formed on the second surface 414 to cover the conductive structure 420, and the first isolation layer 430 has a third surface 432 opposite to the second surface 414. In this step, an epoxy is printed or coated on the second surface 414 of the wafer 800, so as to form the first isolation layer 430 covering the second conductive layer 422 and the laser stopper 424. In addition, a portion of the first isolation layer 430 fills in, but not fully fills the first through hole 418. In some embodiments, the third surface 432 of the first isolation layer 430 is further coated, imprinted, molded or polished to reduce a thickness of the first isolation layer 430.

Continuing in FIG. 8E, a laser is applied to remove a portion of the first isolation layer 430 and form a second though hole 434, and the laser stops at the laser stopper 424 of the conductive structure 420 to expose the laser stopper 424 from the second through hole 434. In this step, the laser is aligned to the laser stopper 424, and the laser stopper 424 acts as a terminal of the laser since the laser is unable to penetrate the laser stopper 424. Therefore, the laser stopper 424 is exposed by the second through hole 434. In some embodiments, the laser is aligned to a location not overlapped with the first through hole 418 in a vertical direction of projection.

Continuing in FIG. 8F, a first conductive layer 440 is formed on the third surface 432 and on the laser stopper 424 exposed from the second though hole 434. After forming the second through hole 434 in the first isolation layer 430, a conductive material is deposited on the third surface 432 of the first isolation layer 430, sidewalls of the second through hole 434 and the laser stopper 424 exposed from the second through hole 434, so as to form the first conductive layer 440. In addition, the first conductive layer 440 in the second through hole 434 is in contact with the laser stopper 424. The conductive material is deposited by using electroless plating in combination with electroplating. In some embodiments, the first conductive layer 440 is formed of copper.

Continuing in FIG. 8G, a passivation layer 450 is formed on the third surface 432 of the first isolation layer 430 and on the first conductive layer 440, and the passivation layer 450 is patterned to form an opening 452 exposing the first conductive layer 440. Then, an external conductive connection 460 is formed in the opening 452. Insulating material is brush-coated on the third surface 432 of the first isolation layer 430 and on the first conductive layer 440, so as to form the passivation layer 450, and the insulating material includes epoxy. In addition, a portion of the passivation layer 450 fills in, but not fully fill the second through hole 434. After that, the passivation layer 450 is patterned to form the opening 452. A portion of the first conductive layer 440 is exposed from the opening 452 of the passivation layer 450, and the external conductive connection 460 is formed in the opening 452. The external conductive connection 460 is electrically connected to the conductive pad 416 by the first conductive layer 440, the laser stopper 424 and the second conductive layer 422.

In some embodiments, the support body 810 on the first surface 412 of the wafer 800 is removed after forming the passivation layer 450. In some embodiments, the support body 810 on the first surface 412 of the wafer 800 is removed after forming the external conductive connection 460.

Continuing in 8H, the wafer 800, the first isolation layer 430 and the passivation layer 450 are diced along a scribe line 820 to form the chip package 400. The wafer 800 is diced alone the scribe line 820 to separate the chips on the wafer, so as to form the chip package 400 shown in FIG. 4.

The embodiments of the present disclosure discussed above have advantages over existing methods and structures, and the advantages are summarized below. The chip package and the fabrication method thereof omit the conventional processes of chemical vapor depositing the first isolation layer and patterning the first isolation layer. In addition, laser is applied to reduce a hole diameter of the through hole, which is benefit for miniaturization design, and further saves process time and machine costs. On the other hand, there is no additional process applied on the first surface of the chip, which has excellent flatness to improve detecting accuracy of the chip package.

Although the present invention has been described in considerable detail with reference to certain embodiments thereof, other embodiments are possible. Therefore, the spirit and scope of the appended claims should not be limited to the description of the embodiments contained herein. Reference will now be made in detail to the embodiments of the invention, examples of which are illustrated in the accompanying drawings. Wherever possible, the same reference numbers are used in the drawings and the description to refer to the same or like parts.

What is claimed is:

1. A chip package, comprising:
a chip having a conductive pad, a first surface and a second surface opposite to the first surface, and the conductive pad being on the first surface;
a first though hole extending from the second surface to the first surface to expose the conductive pad;
a conductive structure disposed on the second surface and extending to the first though hole to contact the conductive pad, the conductive structure comprising a second conductive layer and a laser stopper;
a first isolation layer on the second surface and covering the conductive structure, and the first isolation layer having a third surface opposite to the second surface;
a second though hole extending from the third surface to the second surface to expose the laser stopper; and
a first conductive layer on the third surface and extending to the second though hole to contact the laser stopper.

2. The chip package of claim 1, further comprising:
a passivation layer at the third surface and on the first conductive layer, and the passivation layer having an opening exposing the first conductive layer; and
an external conductive connection in the opening and in contact with the first conductive layer.

3. The chip package of claim 1, wherein a hole diameter of the second through hole is less than a hole diameter of the first through hole.

4. The chip package of claim 1, further comprising a second isolation layer on the second surface and extending into the first through hole to cover sidewalls of the first through hole, and the conductive structure being on the second isolation layer.

5. The chip package of claim 1, wherein a sidewall and a bottom of the second though hole are rough surfaces.

6. The chip package of claim 1, wherein the first through hole and the second through hole are not overlapped in a vertical direction of projection.

7. The chip package of claim 1, wherein a portion of the conductive structure in the first through hole is the second conductive layer, and a portion of the conductive structure on the second surface is the laser stopper.

8. The chip package of claim 7, wherein the laser stopper is a thick copper having a thickness above the second surface, and the thickness being between 5 and 20 micrometers.

9. The chip package of claim 1, wherein the second conductive layer is on the second surface and extending into the first through hole, and the laser stopper being on the second conductive layer.

10. The chip package of claim 9, wherein the laser stopper is a gold bump.

11. The chip package of claim 1, wherein the first isolation layer comprises epoxy.

12. A method of fabricating a chip package, comprising:
providing a wafer with a support body temporary bonding to the wafer, the wafer having a conductive pad, a first surface and a second surface opposite to the first surface, the conductive pad being on the first surface, and the support body covering the first surface and the conductive pad;
forming a first though hole extending from the second surface to the first surface to expose the conductive pad;
forming a conductive structure on the second surface and on the conductive pad exposed from the first though hole, and the conductive structure comprising a second conductive layer and a laser stopper;
forming a first isolation layer on the second surface to cover the conductive structure, and the first isolation layer having a third surface opposite to the second surface;
using a laser to remove a portion of the first isolation layer to form a second though hole, and the laser being stopped at the laser stopper to expose the laser stopper; and
forming a first conductive layer on the third surface and on the laser stopper exposed from the second though hole.

13. The method of fabricating the chip package of claim 12, further comprising:
forming a passivation layer on the third surface of the first isolation layer and on the first conductive layer; and
patterning the passivation layer to form an opening exposing the first conductive layer.

14. The method of fabricating the chip package of claim 13, further comprising forming an external conductive connection in the opening, and the external conductive connection being in contact with the first conductive layer.

15. The method of fabricating the chip package of claim 14, further comprising:
removing the support body; and
dicing the wafer, the first isolation layer and the passivation layer along a scribe line to form the chip package.

16. The method of fabricating the chip package of claim 12, wherein using the laser to remove the portion of the first isolation layer, the laser being aligned to a location not overlapped with the first through hole in a vertical direction of projection.

17. The method of fabricating the chip package of claim 12, wherein forming the conductive structure comprises:
forming the second conductive layer on the conductive pad exposed from the first though hole; and
forming the laser stopper on the second surface, and the second conductive layer and the laser stopper being formed in the same process step.

18. The method of fabricating the chip package of claim 12, wherein forming the conductive structure comprises:
forming the second conductive layer on the second surface and on the conductive pad exposed from the first though hole; and
forming the laser stopper on the second conductive layer, and the second conductive layer and the laser stopper being formed in different process steps.

19. The method of fabricating the chip package of claim 18, wherein the laser stopper is formed on the second conductive layer by a gold bump method.

20. The method of fabricating the chip package of claim 12, further comprising:
forming a second isolation layer on the second surface and in the first through hole; and
patterning the second isolation layer to expose the conductive pad.
